(19) United States
(12) Patent Application Publication
(10) Pub. No.: US 2021/0181439 A1
(43) Pub. Date: Jun. 17, 2021

(54) OPTICAL RECEPTACLE, OPTICAL MODULE, AND OPTICAL TRANSMITTER

(71) Applicant: Enplas Corporation, Saitama (JP)

(72) Inventors: Shimpei MORIOKA, Saitama (JP); Ayano KON, Saitama (JP); Hiroyoshi KANI, Saitama (JP)

(73) Assignee: Enplas Corporation, Saitama (JP)

(21) Appl. No.: 16/761,799

(22) PCT Filed: Oct. 23, 2018
(86) PCT No.: PCT/JP2018/039381

§ 371 Date: May 6, 2020

(30) Foreign Application Priority Data
Nov. 6, 2017 (JP) 2017-213719

(51) Int. Cl. G02B 6/42; H04B 10/50

(52) U.S. Cl. CPC G02B 6/4246; H04B 10/503

(57) ABSTRACT

An optical receptacle capable of demultiplexing an optical signals to be transmitted and received without needing to place an optical functional member on an inclined surface and without needing to use an index-matching material is provided. The optical receptacle comprises: an optical splitter that allows transmitted light entering the optical receptacle from a light-emitting element to proceed to the emission surface toward an optical transmitter, and allows received light entering therein from the optical transmitter to proceed to the emission surface toward a light receiving element; and a light attenuation member for attenuating the received light reaching the light-emitting element from the optical splitter. The optical splitter is formed as an optical surface that includes a fourth optical surface and a fifth optical surface inclined relative to the fourth optical surface. The fourth optical surface is arranged at an angle that allows part of the transmitted light that enters the optical receptacle and reaches the optical splitter to proceed to the second optical surface, and the fifth optical surface is arranged at an angle that allows part of the received light that enters the optical receptacle and reaches the optical splitter to proceed to the third optical surface.

### TECHNICAL FIELD

The present invention relates to an optical receptacle, an optical module and an optical transmitter.

### BACKGROUND ART

In optical communications using an optical transmission member such as an optical fiber, an optical module including a light emitting element such as a surface-emitting laser (e.g., Vertical Cavity Surface Emitting Laser (VCSEL)) is used. The optical module includes an optical receptacle that allows, to enter an end surface of the optical transmission member, transmission light having communication information emitted from the light emitting element.

In addition, in the case where two-way optical communications are performed, an optical module including a light receiving element (e.g., a photodiode (PD)) in addition to a light emitting element is used. The optical receptacle provided in the optical module for two-way optical communications has a configuration in which transmission light emitted from the light emitting element that has entered the optical receptacle reaches an end surface of the optical transmission member, and reception light having communication information emitted from the end surface of the optical transmission member that has entered the optical receptacle reaches the light receiving element. At this time, the optical path of the transmission light that enters the end surface of the optical transmission member and the optical path of the reception light that is entered from the end surface of the optical transmission member are common to each other and parallel to each other in a region near the end surface of the optical transmission member. Therefore, typically, the optical receptacle provided in the optical module for two-way optical communications includes an optical path separation part that separates the optical path of the transmission light and the optical path of the reception light from each other.

For example, PTL 1 discloses an optical member (optical receptacle) that optically couples a transmitting optical element, a receiving optical element, and an optical fiber, and includes an optical functional member such as a half mirror that separates transmitting optical signal and received optical signal from each other. The above-mentioned optical member includes an inclined surface inclined with respect to the optical axis of the optical fiber, and the optical functional member is disposed in the inclined surface. With such a configuration, the optical functional member can operate such that the transmitting optical signal is reflected at the inclined surface so as to be delivered to the optical fiber, and that the received optical signal passes through the inclined surface so as to reach the receiving optical element.

### CITATION LIST

### Patent Literature

### PTL 1

### Japanese Patent Application Laid-Open No. 2009-251375

### SUMMARY OF INVENTION

### Technical Problem

In the optical member disclosed in PTL 1, it is necessary to dispose the optical functional member at an inclined surface. However, installation of the optical functional member at the inclined surface requires fine and exacting operation, and as such the optical member disclosed in PTL 1 easily causes positional displacement of optical functional members. Such positional displacement may result in inclination of the optical axis of the transmitting optical signal or the receiving optical signal, which results displacement of optical coupling between the transmitting optical element and the optical fiber, or between the optical fiber and the receiving optical element, and consequently, the accuracy of optical communications may be reduced.

In addition, in the optical member disclosed in PTL 1, it is necessary to dispose a refractive index adjuster whose refractive index is identical to that of the optical member at the back surface of the inclined surface in order to control the optical path of the received optical signal transmitted through the inclined surface. However, typically, the refractive index adjuster is formed with a material whose thermal expansion coefficient is different from that of the material of the main body of the optical member, and consequently crack may occur in a high temperature test and the like after manufacture of the optical member.

In view of the above-mentioned problems, an object of the present invention is to provide an optical receptacle, an optical module including the optical receptacle and an optical transmitter including the optical module that can separate a transmitting optical signal and a received optical signal from each other without disposing an optical functional member at the inclined surface and without using an refractive index adjuster.

### Solution to Problem

An optical receptacle of the present invention optically couples a light emitting element and an end surface of an optical transmission member, and optically couples the end surface of the optical transmission member and a light receiving element. The optical receptacle includes a first optical surface configured to allow, to enter the optical receptacle, transmission light emitted from the light emitting element; a second optical surface configured to emit, to outside of the optical receptacle, the transmission light entered from the first optical surface such that the transmission light entered from the first optical surface reaches the end surface of the optical transmission member, the second optical surface being configured to allow, to enter the optical receptacle, reception light emitted from the end surface of the optical transmission member; a third optical surface configured to emit, to the outside of the optical receptacle, the reception light entered from the second optical surface such that the reception light entered from the second optical surface reaches the light receiving element; an optical path separation part configured to deliver, to the second optical surface, a part of the transmission light entered from the first optical surface, the optical path separation part being configured to deliver, to the third optical surface, a part of the reception light entered from the second optical surface; and a light attenuation member disposed on an optical path connecting between the first optical surface and the light emitting element, the light attenuation member being configured to attenuate the reception light that reaches the light emitting element from the optical path separation part, wherein the optical path separation part is an optical surface including a fourth optical surface, and a fifth optical surface inclined with respect to the fourth optical surface, wherein the fourth optical surface is disposed at an angle such that the part of the transmission light that has entered the optical receptacle and has reached the optical path separation part advances toward the second optical surface, and wherein the fifth optical surface is disposed at an angle such that the part of reception light that has entered the optical receptacle and has reached the optical path separation part advances toward the third optical surface.

An optical receptacle of the present invention optically couples a light emitting element and an end surface of an optical transmission member, and optically couples the end surface of the optical transmission member and a light receiving element. The optical receptacle includes a first optical surface configured to allow, to enter the optical receptacle, transmission light emitted from the light emitting element; a second optical surface configured to emit, to outside of the optical receptacle, the transmission light entered from the first optical surface such that the transmission light entered from the first optical surface reaches the end surface of the optical transmission member, the second optical surface being configured to allow, to enter the optical receptacle, reception light emitted from the end surface of the optical transmission member; a third optical surface configured to emit, to the outside of the optical receptacle, the reception light entered from the second optical surface such that the reception light entered from the second optical surface reaches the light receiving element; and an optical path separation part configured to deliver, to the second optical surface, a part of the transmission light entered from the first optical surface, the optical path separation part being configured to deliver, to the third optical surface, a part of the reception light entered from the second optical surface, wherein the optical path separation part is an optical surface including a fourth optical surface, and a fifth optical surface inclined with respect to the fourth optical surface, wherein the fourth optical surface is disposed at an angle such that the part of the transmission light that has entered the optical receptacle and has reached the optical path separation part advances toward the second optical surface, and wherein the fifth optical surface is disposed at an angle such that the part of reception light that has entered the optical receptacle and has reached the optical path separation part advances toward the third optical surface. The optical receptacle is used with a light attenuation member disposed on an optical path connecting between the first optical surface and the light emitting element, the light attenuation member being configured to attenuate the reception light that reaches the light emitting element from the optical path separation part.

An optical module of the present invention includes: a photoelectric conversion device including a light emitting element and a light receiving element; and the above-mentioned optical receptacle.

An optical module of the present invention includes: a photoelectric conversion device including a light emitting element and a light receiving element; an optical receptacle configured to optically couple the light emitting element and an end surface of an optical transmission member, and optically couple the end surface of the optical transmission member and the light receiving element, and a light attenuation member. The optical receptacle includes a first optical surface configured to allow, to enter the optical receptacle, transmission light emitted from the light emitting element; a second optical surface configured to emit, to outside of the optical receptacle, the transmission light entered from the first optical surface such that the transmission light entered from the first optical surface reaches the end surface of the optical transmission member, the second optical surface being configured to allow, to enter the optical receptacle, reception light emitted from the end surface of the optical transmission member; a third optical surface configured to emit, to the outside of the optical receptacle, the reception light entered from the second optical surface such that the reception light entered from the second optical surface reaches the light receiving element; and an optical path separation part configured to deliver, to the second optical surface, a part of the transmission light entered from the first optical surface, the optical path separation part being configured to deliver, to the third optical surface, a part of the reception light entered from the second optical surface, wherein the optical path separation part is an optical surface including a fourth optical surface, and a fifth optical surface inclined with respect to the fourth optical surface, wherein the fourth optical surface is disposed at an angle such that the part of the transmission light that has entered the optical receptacle and has reached the optical path separation part advances toward the second optical surface, wherein the fifth optical surface is disposed at an angle such that the part of reception light that has entered the optical receptacle and has reached the optical path separation part advances toward the third optical surface. The light attenuation member is disposed on an optical path connecting between the first optical surface and the light emitting element, the light attenuation member being configured to attenuate the reception light that reaches the light emitting element from the optical path separation part.

An optical transmitter of the present invention includes: an optical transmission member; and two optical modules disposed at both end portions of the optical transmission member, each of the two optical modules being the above-mentioned optical module.

### Advantageous Effects of Invention

According to the present invention, an optical receptacle, an optical module including the optical receptacle and an optical transmitter including the optical module that can separate a transmitting optical signal and a received optical signal from each other without disposing an optical functional member at the inclined surface and without using an refractive index adjuster are provided.

### BRIEF DESCRIPTION OF DRAWINGS

FIG. 1 is a sectional view schematically illustrating a configuration of an optical module of a first embodiment of the present invention;

FIG. 2A is a plan view of an optical receptacle of the first embodiment of the present invention, FIG. 2B is a bottom view of the optical receptacle, FIG. 2C is a front view of the optical receptacle, FIG. 2D is a back view of the optical receptacle, FIG. 2E is a left side view of the optical receptacle, and FIG. 2F is a right side view of the optical receptacle;

FIG. 3A is a partially enlarged sectional view of an optical path separation part in a region indicated with a broken line in FIG. 1, FIG. 3B is a partially enlarged sectional view illustrating optical paths of transmission light in a region near the optical path separation part, and FIG. 3C is a partially enlarged sectional view illustrating optical paths of reception light in a region near the optical path separation part;

FIG. 4 is a sectional view schematically illustrating a configuration of an optical module of a second embodiment of the present invention;

FIG. 5A is a partially enlarged sectional view of an optical path separation part in a region indicated with a broken line in FIG. 4, FIG. 5B is a partially enlarged sectional view illustrating optical paths of transmission light in a region near the optical path separation part, and FIG. 5C is a partially enlarged sectional view illustrating optical paths of reception light in a region near the optical path separation part; and

FIG. 6 is a sectional view schematically illustrating a configuration of an optical transmitter of a third embodiment of the present invention.

### DESCRIPTION OF EMBODIMENTS

Embodiments of the present invention are elaborated below with reference to the accompanying drawings.

### First Embodiment

### Configuration of Optical Module

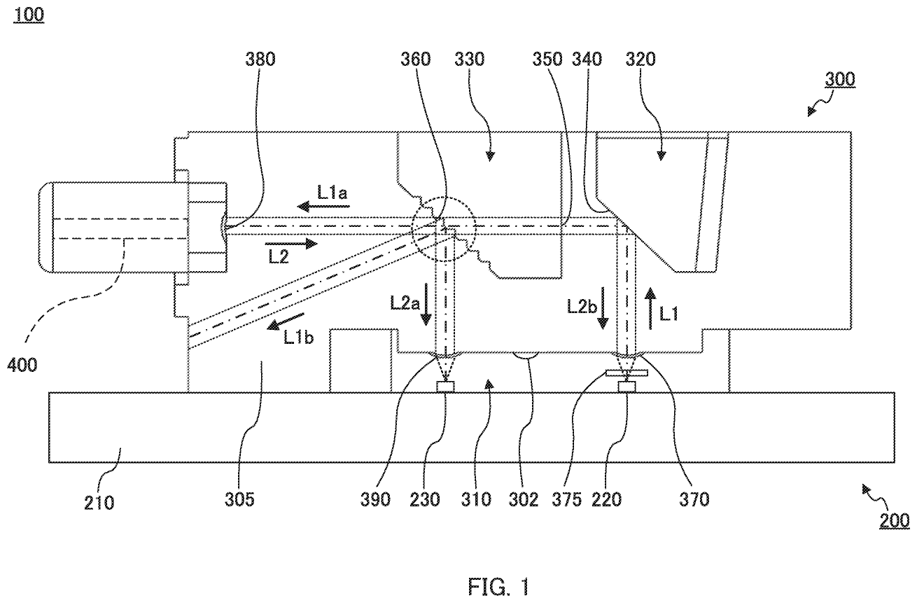

FIG. 1 is a sectional view schematically illustrating a configuration of optical module 100 of a first embodiment of the present invention. In FIG. 1, the dashed line indicates an optical axis, and the broken line indicates the outer diameter of light.

As illustrated in FIG. 1, optical module 100 includes photoelectric conversion device 200 and optical receptacle 300. Optical module 100 is an optical module for two-way communications that can perform both transmission and reception. Optical module 100 is used in the state where optical transmission member 400 is connected to optical receptacle 300.

Photoelectric conversion device 200 includes substrate 210, light emitting element 220 and light receiving element 230.

Substrate 210 holds light emitting element 220, light receiving element 230 and optical receptacle 300. Substrate 210 may be a glass composite substrate, a glass epoxy substrate, or a flexible substrate, for example.

Light emitting element 220 is a transmitting photoelectric conversion element disposed on substrate 210. The number and position of light emitting element 220 are not limited, and may be appropriately set in accordance with the use. In the present embodiment, twelve light emitting elements 220 are arranged on the same straight line along the depth direction of FIG. 1.

Light emitting element 220 emits laser light that is transmission light in a direction perpendicular to the top surface of light emitting element 220. Light emitting element 220 may be a vertical-cavity surface-emitting laser (VCSEL) that emits transmission light from a light-emitting surface (light emission region), for example. In the present embodiment, light emitting element 220 is a VCSEL that emits laser light having a wavelength of 850 nm.

Light receiving element 230 is a receiving photoelectric conversion element disposed on substrate 210. The number and position of light receiving element 230 are not limited, and may be appropriately set in accordance with the use. In the present embodiment, twelve light receiving elements 230 are arranged on the same straight line along the depth direction of FIG. 1.

Light receiving element 230 receives laser light that is reception light emitted from the end surface of optical transmission member 400 and transmitted through the inside of optical receptacle 300. Light receiving element 230 may be a photodiode (PD) that receives and senses reception light at a light reception surface (light reception region). In the present embodiment, light receiving element 230 is a PD that senses laser light having a wavelength of 910 nm.

Optical receptacle 300 is disposed between light emitting element 220 and light receiving element 230, and a plurality of optical transmission members 400, and optically couples light emitting element 220 and the end surface of optical transmission member 400, and the end surface of optical transmission member 400 and light receiving element 230.

Photoelectric conversion device 200 and optical receptacle 300 are fixed with each other with a publicly known fixing member such as an adhesive agent containing thermosetting resin, ultraviolet curing resin and the like, for example.

Optical transmission member 400 is attached to optical receptacle 300 through a publicly known attaching member in the state where an end portion thereof is housed inside a connector. Optical transmission member 400 may be a publicly known optical transmission member such as an optical fiber and a light waveguide. In the present embodiment, optical transmission member 400 is an optical fiber. The optical fiber may be of a single mode type, or a multiple mode type. The number of optical transmission member 400 is not limited, and may be appropriately changed in accordance with the use.

### Configuration of Optical Receptacle

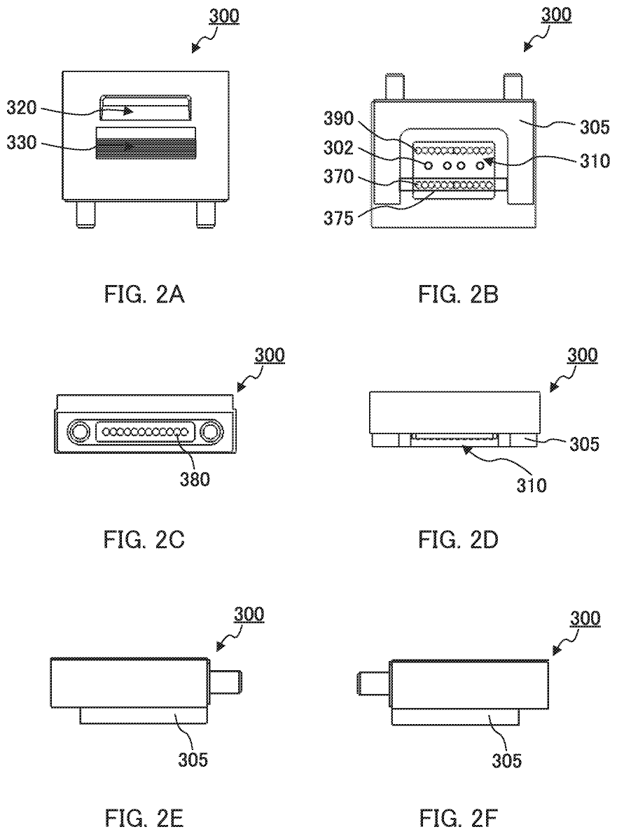

FIGS. 2A to 2F illustrate a configuration of optical receptacle 300 of the present embodiment. FIG. 2A is a plan view of optical receptacle 300, FIG. 2B is a bottom view of optical receptacle 300, FIG. 2C is a front view of optical receptacle 300, FIG. 2D is a back view of optical receptacle 300, FIG. 2E is a left side view of optical receptacle 300, and FIG. 2F is a right side view of optical receptacle 300.

As illustrated in FIG. 1, optical receptacle 300 is disposed on substrate 210 in such a manner as to face light emitting element 220 and light receiving element 230.

The rate of the intensity of transmission light emitted toward optical transmission member 400 from optical receptacle 300 with respect to the intensity of transmission light that enters optical receptacle 300 is 40% to 50%, for example. This rate can be adjusted by a factor such as the amount of a light attenuator and the planar dimension of a fourth optical surface, which will be described later.

Optical receptacle 300 is formed of a material that is optically transparent to light having a wavelength used for optical communications. Examples of such a material include transparent resins such as polyetherimide (PEI) and cyclic olefin resin. Typically, the inside of optical receptacle 300 is filled with the above-mentioned material.

Note that a light attenuator that reduces the intensity of the light (transmission light L1 and reception light L2) passing inside optical receptacle 300 may be added to the material of optical receptacle 300. Examples of the light attenuator include a phthalocyanine organic pigment, and inorganic particles including carbon black, oxidation copper and the like. The amount of the light attenuator in the material of optical receptacle 300 is appropriately selected in accordance with the type of the light attenuator, the optical path length in optical receptacle 300, the type of light emitting element 220 and the like.

In addition, it is preferable to dispose an antireflection film on the surface of optical receptacle 300 from the viewpoint of suppressing reflection of light at the surface. The antireflection film may be disposed over the entire surface of optical receptacle 300, or may be disposed only on first optical surface 370 where transmission light L1 emitted from light emitting element 220 impinges or on second optical surface 380 where reception light L2 emitted from the end surface of optical transmission member 400 impinges. The method of disposing the antireflection film on the surface of optical receptacle 300 is not limited and it suffices to provide antireflection coating (AR coating) on the surface of optical receptacle 300, for example. Examples of the material of the antireflection film include, SiO₂, TiO₂ and MgF₂.

In addition, optical receptacle 300 may include positioning part 302 for alignment of substrate 210 and optical receptacle 300. From the viewpoint of increasing the visibility through optical receptacle 300, it is preferable to provide positioning part 302a at a position where the top surface and the bottom surface of optical receptacle 300 are parallel to each other. From the viewpoint of ease of shaping and accuracy of alignment, it is preferable to dispose positioning part 302 at the bottom surface (the surface facing substrate 210) of optical receptacle 300, except on the optical path. The shape and the size of positioning part 302 may be set as in a common positioning part. Examples of positioning part 302 may include a recess and a protrusion formed in the bottom surface of optical receptacle 300, a pattern formed in the bottom surface of optical receptacle 300, and the like.

As illustrated in FIGS. 2A to 2F, optical receptacle 300 is a member having a substantially cuboid shape. In the present embodiment, first recess 310 having a shape of a substantially rectangular prism surrounded by leg part 305 from three directions is formed in the bottom surface (the surface facing substrate 210) of optical receptacle 300. In the top surface (the surface opposite the bottom surface) of optical receptacle 300, second recess 320 having a substantially pentagonal prism shape and third recess 330 having a substantially pentagonal prism shape are sequentially disposed in the direction toward the side on which optical transmission member 400 is attached in optical receptacle 300. As elaborated later, a part of the inner surface of second recess 320 is transmission light reflection part 340, the other part of the inner surface of third recess 330 is transmission surface 350, and the other part of the inner surface of third recess 330 is optical path separation part 360. The interiors of first recess 310, second recess 320 and third recess 330 are filled with a material (e.g., the atmosphere) having a refractive index lower than that of the material of optical receptacle 300.

Optical receptacle 300 includes first optical surface 370, second optical surface 380, third optical surface 390, optical path separation part 360 and transmission light reflection part 340. In addition, optical receptacle 300 includes light attenuation member 375 on the optical path connecting between first optical surface 370 and light emitting element 220. Light attenuation member 375 may be attached to optical receptacle 300, or may be attached to substrate 210 separately from optical receptacle 300.

In optical receptacle 300, transmission light L1 emitted from light emitting element 220 enters optical receptacle 300 from first optical surface 370, and then reaches second optical surface 380 through transmission light reflection part 340 and optical path separation part 360, and thereafter, the light is emitted from second optical surface 380 to the end portion of optical transmission member 400.

In addition, in optical receptacle 300, reception light L2 emitted from the end portion of optical transmission member 400 enters optical receptacle 300 from second optical surface 380 and travels to third optical surface 390 through optical path separation part 360, and thereafter, the light is emitted from third optical surface 390 such that the light reaches light receiving element 230.

First optical surface 370 is an optical surface that is disposed in the bottom surface of optical receptacle 300 in such a manner as to face light emitting element 220, and first optical surface 370 allows, to enter optical receptacle 300, transmission light L1 emitted from light emitting element 220. First optical surface 370 may be a lens that allows, to enter optical receptacle 300, transmission light L1 emitted from the light-emitting surface (light emission region) of light emitting element 220 while refracting the light so as to convert the light into collimated light.

The number of first optical surface 370 is not limited, and may be appropriately selected in accordance with the use, the number of light emitting elements 220 and the like. In the present embodiment, the number of first optical surfaces 370 is twelve as with light emitting elements 220. Twelve first optical surfaces 370 are disposed in the bottom surface of optical receptacle 300 in such a manner as to face respective twelve light emitting elements 220.

The shape of first optical surface 370 is not limited, and may be a flat surface or a curved surface. In the present embodiment, first optical surface 370 is a convex lens surface protruding toward light emitting element 220. In addition, first optical surface 370 has a circular shape in plan view. Preferably, the central axis of first optical surface 370 is perpendicular to the light-emitting surface of light emitting element 220 (and the surface of substrate 210). In addition, preferably, first optical surface 370 is disposed at a position where the central axis of first optical surface 370 is aligned with the optical axis of transmission light L1 emitted from light emitting element 220.

Transmission light reflection part 340 is an optical surface that constitutes a part of the inner surface of second recess 320, and is inclined such that it comes closer to second optical surface 380 in the direction from the bottom surface toward the top surface of optical receptacle 300. Transmission light reflection part 340 is disposed at a position with an inclination angle such that transmission light reflection part 340 reflects, toward second optical surface 380, transmission light L1 entering optical receptacle 300 from first optical surface 370, by the difference between the refractive index of the material (e.g., resin) of the inside of optical receptacle 300 and the refractive index of the material (e.g., the atmosphere) of the inside of second recess 320. Preferably, the inclination angle of transmission light reflection part 340 is, but not limited to, an angle at which transmission light L1 entering from first optical surface 370 impinges at an incident angle greater than the critical angle so as to be totally reflected. In the present embodiment, the inclination angle of reflection part 340 is 45° (note that in this specification, the angle between two surfaces means the angle smaller than the other) with respect to the optical axis of transmission light L1 entering from first optical surface 370. The shape of transmission light reflection part 340 is not limited, and may be a flat surface or a curved surface. In the present embodiment, the shape of transmission light reflection part 340 is a flat surface.

Transmission surface 350 is an optical surface that constitutes a part of the inner surface of third recess 330, and emits transmission light L1 reflected by transmission light reflection part 340 to the inside of third recess 330, which is the outside of optical receptacle 300. Preferably, transmission surface 350 is a surface perpendicular to the optical axis of transmission light L1 reflected by transmission light reflection part 340. With such a configuration, transmission surface 350 can deliver transmission light L1 reflected by transmission light reflection part 340 to optical path separation part 360 and second optical surface 380 along the shortest route without refracting the light at transmission surface 350, and as a result, the configuration of optical receptacle 300 can be simplified to increase the manufacturability and handleability.

Note that depending on the configuration of optical path separation part 360 and the like, transmission surface 350 may be a surface inclined with respect to the optical axis of transmission light L1 reflected by transmission light reflection part 340 for adjusting the optical path of transmission light L1 through refraction of transmission light L1 reflected by transmission light reflection part 340. In such a case, preferably, transmission surface 350 is inclined such that the distance from second optical surface 380 increases in the direction from the bottom surface toward the top surface of optical receptacle 300 for the purpose of increasing the releasability in injection molding.

Optical path separation part 360 is an optical surface that constitutes a part of the inner surface of third recess 330, and is disposed at a position where transmission light L1 entering from first optical surface 370 and reception light L2 entering from second optical surface 380 reach. Optical path separation part 360 is disposed at a position with an inclination angle such that optical path separation part 360 allows, to reenter optical receptacle 300 and travel toward second optical surface 380, a part of transmission light L1 emitted from transmission surface 350 to the outside of optical receptacle 300 (the inside of third recess 330). Furthermore, optical path separation part 360 is disposed at a position with an inclination angle such that optical path separation part 360 reflects, toward third optical surface 390, a part of reception light L2 that has entered optical receptacle 300 from second optical surface 380, by the difference between the refractive index of the material (e.g., resin) of the inside of optical receptacle 300 and the refractive index of the material (e.g., the atmosphere) of the inside of third recess 330.

Second optical surface 380 is an optical surface disposed in the front surface of optical receptacle 300, and second optical surface 380 emits, toward the end surface of optical transmission member 400, a part of transmission light L1 delivered by optical path separation part 360 to second optical surface 380. At this time, preferably, second optical surface 380 emits, toward the end surface of optical transmission member 400, the part of transmission light L1 while converging the light.

In addition, second optical surface 380 is also a surface that allows, to enter optical receptacle 300, reception light L2 emitted from the end surface of optical transmission member 400. Here, second optical surface 380 may be a lens that allows, to enter optical receptacle 300, reception light L2 emitted from the end surface of optical transmission member 400 while refracting the light so as to convert the light into collimated light.

The number of second optical surfaces 380 is not limited, and may be appropriately selected in accordance with the use. In the present embodiment, the number of second optical surfaces 380 is twelve as with the end surfaces of optical transmission member 400. Twelve second optical surfaces 380 are disposed to face the respective twelve end surfaces of optical transmission member 400 in the front surface of the optical receptacle 300.

The shape of second optical surface 380 is not limited, and may be a flat surface or a curved surface. In the present embodiment, the shape of second optical surface 380 is a convex lens surface protruding toward the end surface of optical transmission member 400. Second optical surface 380 has a circular shape in plan view. Preferably, the central axis of second optical surface 380 is perpendicular to the end surface of optical transmission member 400.

Third optical surface 390 is an optical surface disposed in the bottom surface of optical receptacle 300 in such a manner as to face light receiving element 230, and third optical surface 390 emits reception light L2 that has entered optical receptacle 300 from second optical surface 380 and is reflected by optical path separation part 360 such that the reception light L2 reaches light receiving element 230.

The number of third optical surfaces 390 is not limited, and may be appropriately selected in accordance with the use. In the present embodiment, the number of third optical surfaces 390 is twelve as with twelve light receiving elements 230. Twelve third optical surfaces 390 are disposed in the bottom surface of optical receptacle 300 in such a manner as to face respective twelve light receiving elements 230.

The shape of third optical surface 390 is not limited, and may be a flat surface or a curved surface. In the present embodiment, third optical surface 390 is a convex lens surface protruding toward light receiving element 230.

Light attenuation member 375 may be an optical filter that selectively absorbs light having the wavelength of reception light L2, a half mirror that selectively reflects light having the wavelength of reception light L2, or the like. The attenuation member is not limited as long as the transmittance of the light of the wavelength of reception light L2 is smaller than the light of the wavelength of transmission light L1. In the present embodiment, light attenuation member 375 is an optical filter that absorbs light having a wavelength of wavelength 910 nm while allowing light having a wavelength of 850 nm to pass therethrough.

### Configuration and Function of Optical Path Separation Part

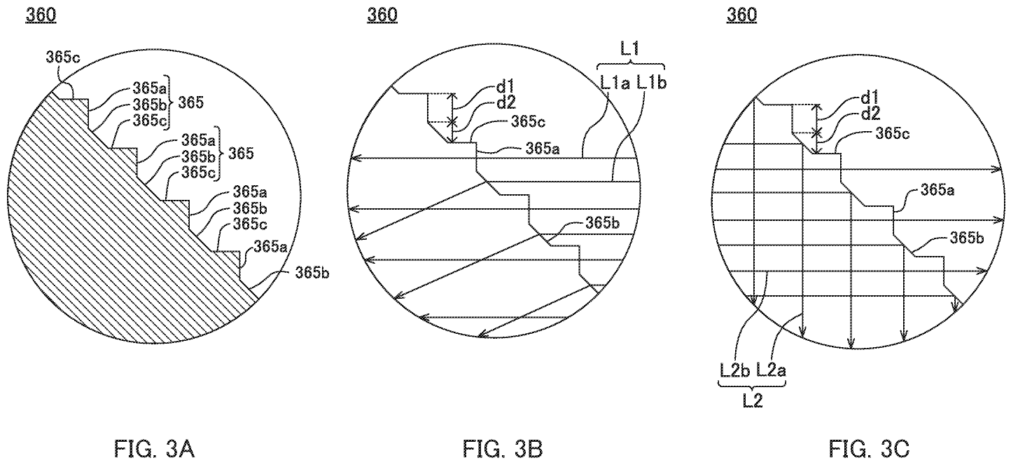

FIGS. 3A to 3C illustrate a configuration of optical path separation part 360 of optical receptacle 300 of the present embodiment. FIG. 3A is a partially enlarged sectional view of the optical path separation part in the region indicated with the broken line in FIG. 1, FIG. 3B is a partially enlarged sectional view illustrating optical paths of transmission light in a region near optical path separation part 360, and FIG. 3C is a partially enlarged sectional view illustrating optical paths of reception light in a region near optical path separation part 360.

Optical path separation part 360 is an optical surface provided with a plurality of separation units 365. Each separation unit 365a has a shape that allows a part of transmission light L1 to pass therethrough toward second optical surface 380 while reflecting a part of reception light L2 toward third optical surface 390. Each separation unit includes fourth optical surface 365a, fifth optical surface 365b inclined with respect to fourth optical surface 365a, and connection surface 365c connecting between fourth optical surface 365a and fifth optical surface 365b. Optical path separation part 360 has a step shape in which a plurality of separation units 365 are arranged.

Fourth optical surface 365a is an optical surface disposed at an angle at which a part of transmission light L1 emitted from transmission surface 350 to the outside of optical receptacle 300 is allowed to pass through fourth optical surface 365a toward second optical surface 380. In the present embodiment, fourth optical surface 365a is a surface perpendicular to the optical axis of transmission light L1 emitted from transmission surface 350 to the outside of optical receptacle 300.

Fifth optical surface 365b is an optical surface disposed at an angle at which a part of reception light L2 that has entered optical receptacle 300 from second optical surface 380 is reflected toward third optical surface 390. In the present embodiment, fifth optical surface 365b is a surface inclined with respect to the optical axis of reception light L2 that has entered optical receptacle 300 from second optical surface 380. In the present embodiment, fifth optical surface 365b is a surface inclined such that the distance from second optical surface 380 (the end surface of optical transmission member 400) increases in the direction from the top surface toward the bottom surface of optical receptacle 300, and fifth optical surface 365b has an inclination angle of 45° with respect to the optical axis of reception light L2 that reaches fifth optical surface 365b. In addition, fifth optical surface 365b has an inclination angle of 135° with respect to fourth optical surface 365a, and an inclination angle of 135° with respect to connection surface 365c.

Connection surface 365c is a surface that connects between fourth optical surface 365a and fifth optical surface 365b, and is parallel to both the optical axis of transmission light L1 that reaches fourth optical surface 365a, and the optical axis of reception light L2 that reaches fifth optical surface 365b. Connection surface 365c has an inclination angle of 90° with respect to fourth optical surface 365a.

Separation units 365 are arranged at an angle such that a plurality of fourth optical surfaces 365a, fifth optical surfaces 365b and connection surfaces 365c thereof are respectively parallel to each other at predetermined intervals in the inclination direction of optical path separation part 360. The number of separation units is not limited, and may be appropriately selected in accordance with the use as long as four to six separation units 365 are disposed within the arrival region of transmission light L1 emitted from transmission surface 350 to the outside of optical receptacle 300 and within the arrival region of reception light L2 emitted from second optical surface 380 to the inside of optical receptacle 300.

As necessary, separation unit 365 may include an optical surface, other than fifth optical surface 365b, that allows a part of transmission light L1 to pass therethrough toward the top surface, the side surface or the bottom surface of optical receptacle 300 except for second optical surface 380, or, an optical surface that reflects a part of reception light L2 toward the top surface, the side surface or the bottom surface of optical receptacle 300 except for third optical surface 390. In addition, as necessary, separation unit 365 may include an optical surface that reflects a part of transmission light L1 toward the top surface, the side surface or the bottom surface of optical receptacle 300 except for second optical surface 380, or, an optical surface that allows a part of reception light L2 to pass therethrough toward the top surface, the side surface or the bottom surface of optical receptacle 300 except for first optical surface 370 and third optical surface 390. Preferably, separation unit 365 includes only fourth optical surface 365a and connection surface 365c as the surface that allows transmission light L1 to pass therethrough, and includes only fifth optical surface 365b as the surface that reflects a part of reception light L2, from a view point of the ease of shaping. In addition, from the viewpoint of suppressing occurrence of cross talk or the like, it is preferable not to include the optical surface that delivers, to third optical surface 390, a part of transmission light L1 entering from first optical surface 370 by reflecting or allowing the light to pass therethrough and separating the light from the other part of transmission light L1.

As illustrated in FIG. 3B, transmission light L1 that is emitted from transmission surface 350 to the outside of optical receptacle 300 so as to reach optical path separation part 360 reenters optical receptacle 300 from fourth optical surface 365a and fifth optical surface 365b.

At this time, since fourth optical surface 365a is perpendicular to the optical axis of the above-mentioned transmission light L1, fourth optical surface 365a allows transmission light L1a that is a part of the transmission light reaching fourth optical surface 365a to pass therethrough in the direction toward second optical surface 380 without refracting the light. With such a configuration, fourth optical surface 365a can deliver, to second optical surface 380 along the shortest route, transmission light L1a that reaches fourth optical surface 365a from transmission light reflection part 340 through transmission surface 350 without refracting the light at fourth optical surface 365a, and as a result, the configuration of optical receptacle 300 can be simplified to increase the manufacturability and handleability. Note that at this time, transmission light reflection part 340, transmission surface 350, optical path separation part 360 and second optical surface 380 are sequentially disposed in the direction toward the side on which optical transmission member 400 is attached in optical receptacle 300, on a straight line that is parallel to the optical path of the transmission light emitted to optical transmission member 400 and the optical path of the reception light entering from optical transmission member 400. In addition, the angles of transmission surface 350, fourth optical surface 365a of optical path separation part 360, and second optical surface 380 are parallel to each other.

On the other hand, fifth optical surface 365b, which is also a surface inclined with respect to the optical axis of the above-mentioned transmission light L1, refracts transmission light L1b that is a part of the transmission light reaching fifth optical surface 365b, by the difference between the refractive index of the material (e.g., the atmosphere) of the inside of third recess 330 and the refractive index of the material (e.g., resin) of the inside of optical receptacle 300. Fifth optical surface 365b functions also as an attenuation part that selectively attenuates transmission light L1 by refracting transmission light L1b in a direction different from second optical surface 380.

Note that no transmission light L1 impinges on connection surface 365c since connection surface 365c is parallel to the incident direction of transmission light L1.

As illustrated in FIG. 3C, incident reception light L2 that enters optical receptacle 300 from second optical surface 380 also reaches optical path separation part 360.

At this time, since fifth optical surface 365b is a surface inclined with respect to the optical axis of the above-mentioned reception light L2, fifth optical surface 365b reflects, toward third optical surface 390, reception light L2a that is a part of the reception light reaching fifth optical surface 365b.

Note that, as illustrated in FIG. 3C, fourth optical surface 365a is a surface perpendicular to the optical axis of reception light L2 that enters optical receptacle 300 from second optical surface 380, and therefore reception light L2b that is a part of the above-mentioned reception light may pass through fourth optical surface 365a so as to reach light emitting element 220 through transmission surface 350, transmission reflection light section 340 and first optical surface 370. In the present embodiment, for the purpose of suppressing occurrence of cross talk due to the above-mentioned reception light L2b reaching light emitting element 220, light attenuation member 375 is provided on the optical path connecting between first optical surface 370 and light emitting element 220.

Note that no reception light L2 impinges on connection surface 365c since connection surface 365c is parallel to the incident direction of reception light L2.

In this manner, in optical path separation part 360 disposed at a position on the optical path of transmission light L1 and the optical path of reception light L2, fourth optical surface 365a functions as an optical surface that delivers, to second optical surface 380, a part of transmission light L1 that enters optical receptacle 300 and reaches optical path separation part 360, and fifth optical surface 365b functions as an optical surface that delivers, to third optical surface 390, a part of reception light L2 that enters optical receptacle 300 and reaches optical path separation part 360. Thus, optical path separation part 360 controls the optical paths inside optical receptacle 300 by separating at least one of the optical path of transmission light L1 and the optical path of reception light L2.

It suffices that light attenuation member 375 is a member that attenuates reception light L2b reaching light emitting element 220 from optical path separation part 360 (fourth optical surface 365a), and does not significantly attenuates delivery of transmission light L1a from light emitting element 220 to optical path separation part 360 (fourth optical surface 365a). Light attenuation member 375 may be an optical filter that selectively absorbs the light of the wavelength of reception light L2, a half mirror that selectively reflects the light of the wavelength of reception light L2 or the like. The above-mentioned attenuation member is not limited as long as the transmittance of the light of the wavelength of reception light L2 is smaller than the transmittance of the light of the wavelength of transmission light L1. In the present embodiment, light attenuation member 375 is an optical filter that allows, to pass therethrough, light having a wavelength of 850 nm, and absorbs light having a wavelength of 910 nm.

In transmission light L1, the ratio between the light quantity of transmission light L1 a delivered to second optical surface 380 through fourth optical surface 365a and the light quantity of transmission light L1b refracted by fifth optical surface 365b so as not to reach second optical surface 380 is substantially the same as the area ratio between fourth optical surface 365a and fifth optical surface 365b in optical path separation part 360 as viewed from transmission light reflection part 340 side. In addition, in reception light L2, the ratio between the light quantity of reception light L2b that passes through fourth optical surface 365a so as not to reach third optical surface 390 and the light quantity of reception light L2a that is reflected by fifth optical surface 365b toward third optical surface 390 is substantially the same as the area ratio between fourth optical surface 365a and fifth optical surface 365b in optical path separation part 360 as viewed from second optical surface 380 side. In the present embodiment, transmission light reflection part 340, transmission surface 350, optical path separation part 360 and second optical surface 380 are sequentially disposed on a straight line, and therefore the ratio between the light quantity of transmission light L1 a and the light quantity of transmission light L1b is the same as the ratio between the light quantity of reception light L2b and the light quantity of reception light L2a. The above-mentioned two light quantity ratios are substantially the same as the area ratio between fourth optical surface 365a and fifth optical surface 365b in optical path separation part 360 as viewed from transmission light reflection part 340 side (and is substantially the same as the length ratio between d1 and d2 of FIGS. 3B and 3C), and can be adjusted by changing the ratio between d1 and d2. It is preferable that the proportion of d2 be greater than the proportion of d1 from the viewpoint of increasing the attenuation rate of transmission light L1 by optical path separation part 360, and also from the viewpoint of suppressing occurrence of cross talk due to reception light L2b transmitted through fourth optical surface. From the above-mentioned viewpoints, d1:d2 is preferably 5:5 to 9:1, more preferably 7:3 to 8:2.

### Optical Paths in Optical Module

Transmission light L1 that is laser light having a wavelength of 850 nm emitted from light emitting element 220 enters optical receptacle 300 from first optical surface 370. At this time, transmission light L1 is converted to collimated light by first optical surface 370. Next, transmission light L1 entering optical receptacle 300 from first optical surface 370 is reflected by transmission light reflection part 340 toward optical path separation part 360. Transmission light L1 reflected by transmission light reflection part 340 is emitted from transmission surface 350 to the outside of optical receptacle 300 so as to reach optical path separation part 360 and reenter optical receptacle 300. At this time, transmission light L1 a that is a part of transmission light L1 reaching optical path separation part 360 passes through fourth optical surface 365a and reaches second optical surface 380. At the same time, transmission light L1b that is the other part of transmission light L1 reaching optical path separation part 360 is refracted by fifth optical surface 365b, and therefore does not reach second optical surface 380. With such a configuration, transmission light L1 is attenuated by optical path separation part 360. Transmission light L1a reaching second optical surface 380 through fourth optical surface 365a is emitted from second optical surface 380 to the outside of optical receptacle 300, and reaches the end surface of optical transmission member 400.

On the other hand, reception light L2 that is laser light having a wavelength of 910 nm emitted from the end surface of optical transmission member 400 enters optical receptacle 300 from second optical surface 380. At this time, reception light L2 is converted to collimated light by second optical surface 380. Next, reception light L2a that is a part of reception light L2 entering optical receptacle 300 from second optical surface 380 reaches optical path separation part 360 so as to be reflected by fifth optical surface 365b, and reaches third optical surface 390. Reception light L2a that is reflected by fifth optical surface 365b so as to reach third optical surface 390 is emitted to the outside of optical receptacle 300 from third optical surface 390, and reaches light receiving element 230. On the other hand, reception light L2b that is the other part of reception light L2 entering optical receptacle 300 from second optical surface 380 is emitted to the outside of optical receptacle 300 through fourth optical surface 365a passes through transmission surface 350 and reenters optical receptacle 300 so as to be reflected by transmission light reflection part 340 toward first optical surface 370. Reception light L2b having reached first optical surface 370 is emitted to the outside of optical receptacle 300 toward light emitting element 220, but is absorbed and attenuated by light attenuation member 375 that is an optical filter configured to selectively absorb light having a wavelength of 910 nm, and thus, occurrence of cross talk due to reception light L2b reaching light emitting element 220 is suppressed.

### Effect

As described above, in optical receptacle 300 according to the present embodiment, optical path separation part 360 separates the optical path of reception light L2 from the optical path of transmission light L1, and thus separates light into a transmitting optical signal and a reception optical signal. Thus, optical receptacle 300 according to the present embodiment does not require an optical functional member such as a half mirror at the inclined surface corresponding to optical path separation part 360, and therefore reduction in accuracy of optical communications due to positional displacement of the optical functional member is suppressed.

In addition, in optical receptacle 300 according to the present embodiment, it is not necessary to dispose an optical functional member such as a half mirror at the above-mentioned inclined surface, and therefore it is not necessary to use a refractive index adjuster for adjusting the optical path of light passing through the above-mentioned inclined surface. Therefore, optical receptacle 300 according to the present embodiment can suppress crack in a high temperature test after manufacture of optical receptacle 300 due to the difference between the thermal expansion coefficient of the material of the refractive index adjuster and the thermal expansion coefficient of the material of optical receptacle 300.

### Second Embodiment

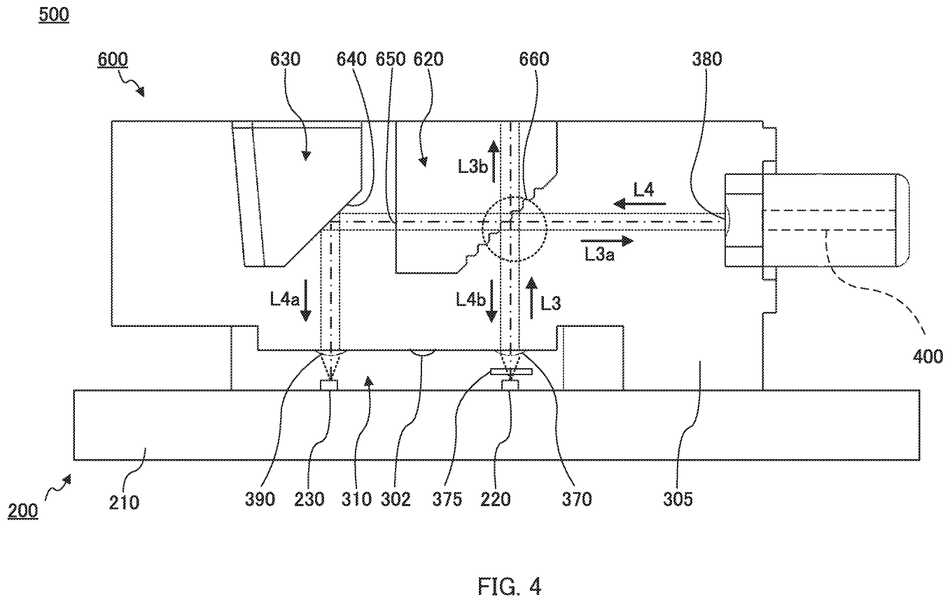

FIG. 4 is a sectional view schematically illustrating a configuration of optical module 500 of a second embodiment of the present invention. In FIG. 4, the dashed line indicates an optical axis, and the broken line indicates the outer diameter of light.

Optical module 500 of the second embodiment differs from optical module 500 of the first embodiment in that the wavelength of laser light emitted by light emitting element 220 that is a VCSEL is 910 nm, and that the wavelength of the laser light sensed by light receiving element 230 that is a PD is 850 nm. Further, optical module 500 of the second embodiment differs from optical module 500 of the first embodiment in the configuration of optical receptacle 600. Therefore, in the present embodiment, the component same as those of the first embodiment are denoted with the same reference numerals and the description thereof will be omitted.

### Configuration of Optical Module

As illustrated in FIG. 4, optical module 500 includes photoelectric conversion device 200 in which light emitting element 220 and light receiving element 230 disposed on substrate 210, and optical receptacle 600. Optical module 500 is an optical module for two-way communications that can perform both transmission and reception. Optical module 500 is used in the state where optical receptacle 600 is connected to optical transmission member 400.

### Configuration of Optical Receptacle

As in the first embodiment, optical receptacle 600 is disposed over substrate 210 in such a manner as face light emitting element 220 and light receiving element 230.

The ratio of the intensity of transmission light emitted from optical receptacle 600 to optical transmission member 400 to the intensity of transmission light that enters optical receptacle 600 is, for example, 40% to 50%. This ratio can be adjusted by the amount of the light attenuator, the planar dimension of a fourth optical surface described later, and the like.

As in the first embodiment, optical receptacle 600 is a member having a substantially cuboid shape, and in the bottom surface (the surface facing substrate 210), first recess 310 having a substantially rectangular prism shape that is surrounded by leg part 305 from three directions is formed. In the top surface (the surface opposite the bottom surface) of optical receptacle 600, fourth recess 620 having a substantially pentagonal prism shape and fifth recess 630 having a substantially pentagonal prism shape are sequentially disposed in the direction away from the side on which optical transmission member 400 is attached in optical receptacle 600. A part of the inner surface of fourth recess 620 is optical path separation part 660, and another part of the inner surface of fourth recess 620 is transmission surface 650, and, a part of the inner surface of fifth recess 630 is reception light reflection part 640. The inside of first recess 310, fourth recess 620 and fifth recess 630 is filled with a material (e.g., the atmosphere) whose refractive index is lower than that of the material of optical receptacle 600.

Optical receptacle 600 includes first optical surface 370, second optical surface 380, third optical surface 390, optical path separation part 660 and reception light reflection part 640. In addition, optical receptacle 600 includes light attenuation member 375 on the optical path connecting between first optical surface 370 and light emitting element 220. In addition, optical receptacle 600 includes positioning part 302 at a position in bottom surface (the surface facing substrate 210) except for the optical path.

Optical receptacle 600 allows transmission light L3 emitted from light emitting element 220 to enter optical receptacle 600 from first optical surface 370, and delivers the light to second optical surface 380 through optical path separation part 660 such that the light is emitted from second optical surface 380 to the end portion of optical transmission member 400.

In addition, optical receptacle 600 allows reception light L4 emitted from the end portion of optical transmission member 400 to enter optical receptacle 600 from second optical surface 380, and delivers the light to third optical surface 390 through optical path separation part 660 and reception light reflection part 640 such that the light is emitted from third optical surface 390 and delivered to light receiving element 230.

Note that the shape, function, position, number and the like of first optical surface 370, second optical surface 380 and third optical surface 390 may be the same as those of first embodiment, and therefore detailed description thereof is omitted.

Optical path separation part 660 is an optical surface that constitutes a part of the inner surface of fourth recess 620, and is disposed at a position where transmission light L3 entered from first optical surface 370 and reception light L4 entered from second optical surface 380 reach. Optical path separation part 660 is disposed at a position with an inclination angle such that optical path separation part 660 reflects, toward second optical surface 380, a part of transmission light L3 entering optical receptacle 600 from first optical surface 370, by the difference between the refractive index of the material (e.g., resin) of the inside of optical receptacle 600 and the refractive index of the material (e.g., the atmosphere) of the inside of fourth recess 620. Furthermore, optical path separation part 660 is disposed at a position with an inclination angle such that optical path separation part 660 emits a part of reception light L4 entering optical receptacle 600 from second optical surface 380 toward the inside of fourth recess 620, which is the outside of optical receptacle 600.

Transmission surface 650 is another optical surface that constitutes a part of the inner surface of fourth recess 620, and allows, to reenter optical receptacle 600, reception light L4 emitted to the outside of optical receptacle 600 from optical path separation part 660. Preferably, transmission surface 650 is perpendicular to the optical axis of reception light L4 that is emitted to the outside of optical receptacle 600 (inside of fourth recess 620) from optical path separation part 660. With such a configuration, transmission surface 650 can allow, to reenter optical receptacle 600 along the shortest route, reception light L4 emitted from optical path separation part 660 and can deliver the light to reception light reflection part 640 without refracting the light at transmission surface 650. Thus, the configuration of optical receptacle 600 can be simplified and the manufacturability and handleability can be increased.

Note that depending on the configuration of optical path separation part 660 and the like, transmission surface 650 may be a surface that is inclined with respect to the optical axis of reception light L4 emitted to the outside of optical receptacle 600 from optical path separation part 660 and is configured to adjust the optical path of reception light L4 by refracting reception light L4 emitted from optical path separation part 660. In this case, preferably, transmission surface 650 is inclined such that the distance from second optical surface 380 increases in the direction from the bottom surface toward the top surface of optical receptacle 600 for the purpose of increasing the releasability in injection molding.

Reception light reflection part 640 is an optical surface that constitutes a part of the inner surface of fifth recess 630, and is a surface that is inclined such that it comes closer to second optical surface 380 in the direction from the bottom surface toward the top surface of optical receptacle 600. Reception light reflection part 640 is disposed at a position with an inclination angle such that reception light reflection part 640 reflects, toward third optical surface 390, reception light L4 reentering optical receptacle 600 from transmission surface 650, by the difference between the refractive index of the material (e.g., resin) of the inside of optical receptacle 600 and the refractive index of the material (e.g., the atmosphere) of the inside of fifth recess 630. Preferably, the inclination angle of reception light reflection part 640 is, but not limited to, an angle at which reception light L4 reentering optical receptacle 600 from transmission surface 650 impinges thereto at an incident angle greater than the critical angle so as to be totally reflected. In the present embodiment, the inclination angle of reception light reflection part 640 is 45° with respect to the optical axis of reception light L4 reentering optical receptacle 600 from transmission surface 650. The shape of reception light reflection part 640 is not limited, and may be a flat surface or a curved surface. In the present embodiment, the shape of reception light reflection part 640 is a flat surface.

### Configuration and Function of Optical Path Separation Part

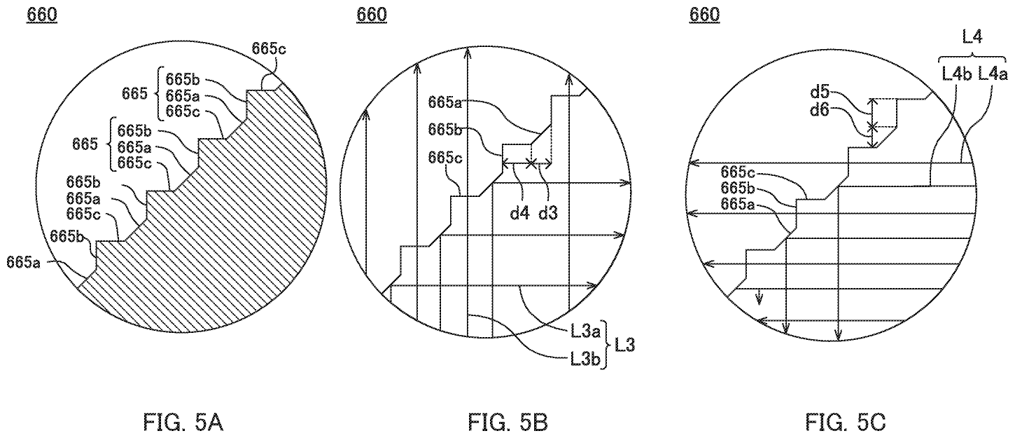

FIGS. 5A to 5C illustrate a configuration of optical path separation part 660 of optical receptacle 600 of the present embodiment. FIG. 5A is a partially enlarged sectional view of the region indicated with the broken line in FIG. 4, FIG. 5B is a partially enlarged sectional view illustrating optical paths of transmission light in a region near optical path separation part 660, and FIG. 5C is a partially enlarged sectional view illustrating optical paths of reception light in a region near optical path separation part 660.

Optical path separation part 660 is an optical surface provided with a plurality of separation units 665. Each separation unit 665 has a shape that reflects a part of transmission light L3 toward second optical surface 380, and allows a part of reception light L4 to pass therethrough toward third optical surface 390. Each separation unit includes fourth optical surface 665a, fifth optical surface 665b inclined with respect to fourth optical surface 665a, and connection surface 665c connecting between fourth optical surface 665a and fifth optical surface 665b. Optical path separation part 660 has a step shape in which a plurality of separation units 665 are arranged.

Fourth optical surface 665a is an optical surface disposed at an angle at which a part of transmission light L3 entering optical receptacle 600 from first optical surface 370 is reflected toward second optical surface 380. In the present embodiment, fourth optical surface 665a is a surface inclined with respect to optical axis of transmission light L3 entering optical receptacle 600 from first optical surface 370. In the present embodiment, fourth optical surface 665a is a surface inclined such that the distance from second optical surface 380 (the end surface of optical transmission member 400) increases in the direction from the top surface toward the bottom surface of optical receptacle 600, and fourth optical surface 665a has an inclination angle of 45° with respect to optical axis of transmission light L3 reaching fourth optical surface 665a. In addition, fourth optical surface 665a has an inclination angle of 135° with respect to fifth optical surface 665b, and an inclination angle of 135° with respect to connection surface 665c.

Fifth optical surface 665b is an optical surface disposed at an angle at which fifth optical surface 665b allows, to pass therethrough toward third optical surface 390, a part of reception light L4 entering optical receptacle 600 from second optical surface 380, and in the present embodiment, fifth optical surface 665b is perpendicular to the optical axis of reception light L4 entering optical receptacle 600 from second optical surface 380.

Connection surface 665c is a surface connecting between fourth optical surface 665a and fifth optical surface 665b. Connection surface 665c is perpendicular to the optical axis of transmission light L3 reaching fourth optical surface 665a, and is parallel to the optical axis of reception light L4 reaching fifth optical surface 665b. Connection surface 665c has an inclination angle of 90° with respect to fourth optical surface 665a. Separation units 665 are arranged at an angle such that fourth optical surfaces 665a, fifth optical surfaces 665b and connection surfaces 665c thereof are respectively parallel to each other at predetermined intervals in the inclination direction of optical path separation part 660. The number of separation units is not limited, and may be appropriately selected in accordance with the use as long as four to six separation units 665 are disposed within the arrival region of transmission light L3 entering optical receptacle 600 from first optical surface 370, and within the arrival region of reception light L4 entering optical receptacle 600 from second optical surface 380.

As necessary, separation unit 665 may include an optical surface that reflects a part of transmission light L3 toward the top surface, the side surface or the bottom surface of optical receptacle 600 except for second optical surface 380, or an optical surface that allows a part of reception light L4 to pass therethrough toward the top surface, the side surface or the bottom surface of optical receptacle 600 except for third optical surface 390. In addition, as necessary, separation unit 665 may include an optical surface, other than connection surface 665c, that allows a part of transmission light L3 to pass therethrough toward the top surface, the side surface or the bottom surface of optical receptacle 600 except for second optical surface 380, or, an optical surface that allows a part of reception light L4 to pass therethrough toward the top surface, the side surface or the bottom surface of optical receptacle 600 except for first optical surface 370 and third optical surface 390. From a view point of the ease of shaping, it is preferable that separation unit 665 include only fourth optical surface 665a as the surface that reflects a part of transmission light L3, and include only fifth optical surface 665b as the surface that allows a part of reception light L4 to pass therethrough. In addition, from the viewpoint of suppressing occurrence of cross talk or the like, it is preferable not to include the optical surface that delivers, to third optical surface 390, a part of transmission light L3 entering from first optical surface 370 by reflecting or allowing the light to pass therethrough and separating the light from the other part of transmission light L3.

As illustrated in FIG. 5B, transmission light L3 entering optical receptacle 600 from first optical surface 370 reaches optical path separation part 660.

At this time, since fourth optical surface 665a is a surface inclined with respect to the optical axis of the above-mentioned transmission light L3, fourth optical surface 665a reflects, in the direction toward second optical surface 380, transmission light L3a that is a part of the transmission light reaching fourth optical surface 665a.

On the other hand, since fifth optical surface 665b is parallel to the incident direction of transmission light L3, no transmission light L3 impinges on fifth optical surface 665b.

In addition, since connection surface 665c is a surface perpendicular to the optical axis of the above-mentioned transmission light L3, connection surface 665c allows, to pass therethrough, transmission light L3b that is a part of the above-mentioned transmission light. Connection surface 665c allows to pass therethrough transmission light L3b such that the light travels in a direction different from second optical surface 380, and thus functions also as an attenuation part that selectively attenuates transmission light L3.

As illustrated in FIG. 5C, reception light L4 entering optical receptacle 600 from second optical surface 380 also reaches optical path separation part 660.

At this time, since fifth optical surface 665b is a surface perpendicular to the optical axis of the above-mentioned reception light L4, fifth optical surface 665b allows reception light L4a that is a part of the transmission light reaching fifth optical surface 665b to pass therethrough toward the outside of optical receptacle 600 (the inside of fourth recess 620) and toward transmission surface 650 without refracting the light. With such a configuration, fifth optical surface 665b can deliver, to third optical surface 390 along the shortest route, reception light L4a entering optical receptacle 600 from second optical surface 380 without refracting the light at fifth optical surface 665b. Thus, the configuration of optical receptacle 600 can be simplified and the manufacturability and handleability can be increased. Note that, here, second optical surface 380, optical path separation part 660, transmission surface 650 and reception light reflection part 640 are sequentially disposed on a straight line parallel to the optical path of the transmission light emitted to optical transmission member 400 and the optical path of the reception light entering from optical transmission member 400 in the direction away from the side on which optical transmission member 400 is attached in optical receptacle 600. In addition, the angles of second optical surface 380, fifth optical surface 665b of optical path separation part 660, and transmission surface 650 are parallel to each other.

On the other hand, since fourth optical surface 665a is a surface inclined with respect to the optical axis of the above-mentioned reception light L4, fourth optical surface 665a reflects reception light L4b that is a part of the reception light reaching fourth optical surface 665a, by the difference between the refractive index of the material (e.g., the atmosphere) of the inside of fourth recess 620 and the refractive index of the material (e.g., resin) of the inside of optical receptacle 600. At this time, the reflected reception light L4b may reach light emitting element 220 through first optical surface 370. Also in the present embodiment, for the purpose of suppressing occurrence of cross talk due to reception light L4b reaching light emitting element 220, light attenuation member 375 is provided on the optical path connecting between first optical surface 370 and light emitting element 220. The configuration, the position, the number and the like of light attenuation member 375 may be the same as in the first embodiment, and therefore the detailed description thereof is omitted. Note that in the present embodiment, light attenuation member 375 is an optical filter that allows light having a wavelength of 910 nm to pass therethrough, and absorbs light having a wavelength of 850 nm.

Note that since connection surface 665c is parallel to the incident direction of reception light L4, no reception light L4 impinges on connection surface 665c.

In this manner, in optical path separation part 660 disposed at a position on the optical path of transmission light L3, and on the optical path of reception light L4, fourth optical surface 665a functions as an optical surface that delivers, to second optical surface 380, a part of transmission light L3 entering optical receptacle 600 and reaching optical path separation part 660, and fifth optical surface 665b functions as an optical surface that delivers, to third optical surface 390, a part of reception light L4 entering optical receptacle 600 and reaching optical path separation part 660. Thus, optical path separation part 660 controls the optical paths inside optical receptacle 300 by separating the optical path of transmission light L3 from the optical path of reception light L4.

The light quantity ratio between the light quantity of transmission light L3a that is delivered by fourth optical surface 665a to second optical surface 380 and the light quantity of transmission light L3b that passes through fifth optical surface 665c so as not to reach second optical surface 380 in transmission light L3 is substantially the same as the area ratio between fourth optical surface 665a and connection surface 665c in optical path separation part 660 as viewed from first optical surface 370 side (and is substantially the same as the length ratio between d3 and d4 of FIG. 5B), and can be adjusted by changing the ratio between d3 and d4. From the viewpoint of increasing the attenuation rate of transmission light L3 by optical path separation part 660, it is preferable that the proportion of d4 be large. In view of this, preferably, d3:d4 is 5:5 to 1:9, more preferably 3:7 to 2:8.

In addition, the light quantity ratio between the light quantity of reception light L4a that passes through fifth optical surface 665b toward third optical surface 390 and the light quantity of reception light L4b that is reflected by fourth optical surface 665a so as not to reach third optical surface 390 in reception light L4 is substantially the same as the area ratio between fifth optical surface 665b and fourth optical surface 665a in optical path separation part 660 as viewed from second optical surface 380 side (and is substantially the same as the length ratio between d5 and d6 of FIG. 5C), and can be adjusted by changing the ratio between d5 and d6. From the viewpoint of increasing the reception sensitivity by increasing the proportion of reception light L4a that reaches light receiving element 230, and the view point of suppressing occurrence of cross talk due to arrival of reception light L4b of light emitting element 220, it is preferable that the proportion of d5 be large. In view of this, preferably, d5:d6 is 5:5 to 9:1, more preferably 7:3 to 8:2.

### Optical Paths in Optical Module

Transmission light L3 that is laser light emitted from light emitting element 220 and having a wavelength of 910 nm enters optical receptacle 600 from first optical surface 370. At this time, transmission light L3 is converted to collimated light by first optical surface 370. Next, transmission light L3a that is a part of transmission light L3 entering optical receptacle 600 from first optical surface 370 reaches optical path separation part 660, and is reflected by fourth optical surface 665a toward second optical surface 380. On the other hand, transmission light L3b that is the other part of transmission light L3 reaching optical path separation part 660 passes through connection surface 665c and as such does not reach second optical surface 380. Thus, transmission light L3 is attenuated by optical path separation part 660. Transmission light L3a reflected by fourth optical surface 665a so as to reach second optical surface 380 is emitted to the outside of optical receptacle 600 from second optical surface 380 so as to reach the end surface of optical transmission member 400.

On the other hand, reception light L4 that is laser light having a wavelength of 850 nm emitted from the end surface of optical transmission member 400 enters optical receptacle 600 from second optical surface 380. At this time, reception light L4 is converted to collimated light by second optical surface 380. Next, reception light L4a that is a part of reception light L4 entering optical receptacle 600 from second optical surface 380 reaches optical path separation part 660 and is emitted to the outside of optical receptacle 600 (the inside of fourth recess 620) through fifth optical surface 665b. Reception light L4a emitted to the outside of optical receptacle 600 (the inside of fourth recess 620) reenters optical receptacle 600 through transmission surface 650, and is reflected by reception light reflection part 640 toward third optical surface 390. Reception light L4a reflected toward third optical surface 390 is emitted from third optical surface 390 to the outside of optical receptacle 600, and reaches light receiving element 230. On the other hand, reception light L4b that is the other part of reception light L4 entering optical receptacle 600 from second optical surface 380 is reflected by fourth optical surface 665a toward first optical surface 370. Reception light L4b having reached first optical surface 370 is emitted to the outside of optical receptacle 600 toward light emitting element 220, but is absorbed and attenuated by light attenuation member 375, which is an optical filter that absorbs light having a wavelength of 850 nm. Thus, occurrence of cross talk due to reception light L4b reaching light emitting element 220 is suppressed.

### Effect

As described above, in optical receptacle 600 according to the present embodiment, optical path separation part 660 separates the optical path of reception light L3 from the optical path of transmission light L4, and thus separates light into a transmitting optical signal and a reception optical signal. Thus, optical receptacle 600 according to the present embodiment does not require an optical functional member such as a half mirror at the inclined surface corresponding to optical path separation part 660, and reduction in accuracy of optical communications due to positional displacement of the optical functional member is suppressed.

In addition, in optical receptacle 600 according to the present embodiment, it is not necessary to dispose an optical functional member such as a half mirror at the above-mentioned inclined surface, and therefore it is not necessary to use a refractive index adjuster for adjusting the optical path of light passing through the above-mentioned inclined surface. Therefore, optical receptacle 600 according to the present embodiment can suppress crack in a high temperature test after manufacture of optical receptacle 600 due to the difference between the thermal expansion coefficient of the material of the refractive index adjuster and the thermal expansion coefficient of the material of optical receptacle 600.

In addition, in optical receptacle 600 according to the present embodiment, the attenuation rate of transmission light L3 (proportion of d4 to d3) and the attenuation rate of reception light L4 (the proportion of reception light L4 that reaches light receiving element 230: the proportion of d5 to d6) can be independently controlled.

### Third Embodiment

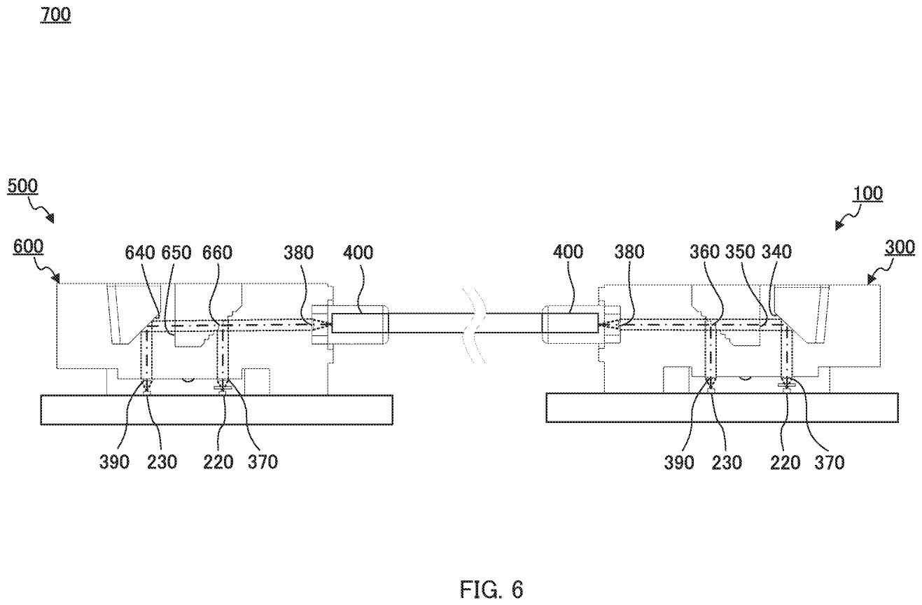

FIG. 6 is a sectional view schematically illustrating a configuration of optical transmitter 700 of a third embodiment of the present invention.

As illustrated in FIG. 6, optical transmitter 700 includes optical transmission member 400, and optical module 100 of the first embodiment and optical module 500 of the second embodiment which are disposed at both end portions of optical transmission member 400.

Transmission light L1 that is laser light having a wavelength of 850 nm emitted from light emitting element 220 of optical module 100 enters optical receptacle 300 from first optical surface 370 and passes through transmission light reflection part 340, transmission surface 350, optical path separation part 360, and second optical surface 380 in this order. In this manner, transmission light L1a that is a part of transmission light L1 having passed through fourth optical surface 365a of optical path separation part 360 is emitted to the outside of optical receptacle 300 from second optical surface 380 so as to reach the end surface of optical transmission member 400. Thereafter, transmission light L1a passes through the inside of optical transmission member 400, and reaches the end surface of optical transmission member 400 on optical module 500 side. The laser light having reached the end surface on optical module 500 side is emitted from the end surface, and becomes reception light L4. Reception light L4 passes through second optical surface 380, optical path separation part 660, transmission surface 650, reception light reflection part 640, and third optical surface 390 in this order. With such a configuration, reception light L4a that is a part of reception light L4 having passed through fifth optical surface 660b of optical path separation part 660 is emitted to the outside of optical receptacle 600 from third optical surface 390, and reaches light receiving element 230.

On the other hand, transmission light L3 that is laser light emitted from light emitting element 220 of optical module 500 and having a wavelength of 850 nm enters optical receptacle 600 from first optical surface 370, and passes through optical path separation part 660 and second optical surface 380 in this order. In this manner, transmission light L3a that is a part of transmission light L3 that is reflected by fourth optical surface 665a of optical path separation part 660 is emitted to the outside of optical receptacle 600 from second optical surface 380, and reaches the end surface of optical transmission member 400. Thereafter, transmission light L3a passes through the inside of optical transmission member 400, and reaches the end surface of optical transmission member 400 on optical module 100 side. The laser light having reached the end surface on optical module 100 side is emitted from the end surface, and becomes reception light L2. Reception light L2 passes through second optical surface 380 and optical path separation part 360 in this order. In this manner, reception light L2a that is a part of reception light L2 reflected by fifth optical surface 360b of optical path separation part 360 is emitted to the outside of optical receptacle 300 from third optical surface 390, and reaches light receiving element 230.

### Effect

As described above, optical transmitter 700 according to the present embodiment separates a signal into a transmitting optical signal and a receiving optical signal in such a manner that optical path separation part 360 of optical receptacle 300 of optical module 100 separates the optical path of reception light L2 from the optical path of transmission light L1, and that optical path separation part 660 of optical receptacle 600 of optical module 500 separates the optical path of transmission light L3 from the optical path of reception light L4. Thus, optical transmitter 700 according to the present embodiment can achieve two-way communications while suppressing reduction in accuracy of optical communications due to positional displacement of the optical functional member.

### Other Embodiments

While the invention made by the present inventor has been specifically described based on the preferred embodiments, it is not intended to limit the present invention to the above-mentioned preferred embodiments but the present invention may be further modified within the scope and spirit of the invention defined by the appended claims.

For example, while the optical receptacle includes four to six separation units in the first to third embodiments, the number of the separation units of the optical receptacle is not limited, and may be one to three, or seven or more.

In addition, while the light emitting element and the light receiving element are mounted on the same substrate and disposed on the same plane in the first to third embodiments, they may be mounted on different substrates, and may be disposed on different planes. For example, the light emitting element of the first embodiment may be disposed on a plane perpendicular to the light receiving element. In this manner, the light emitting element can be disposed on the same straight line as that of the transmission surface, the optical path separation part and the second optical surface, and the transmission light reflection part is not required, and therefore, the manufacturability and handleability can be increased by simplifying the configuration of the optical receptacle. Likewise, the light receiving element of the second embodiment may be disposed on a plane perpendicular to the light emitting element.

In addition, while the light attenuation member is disposed apart from both the first optical surface and the light emitting element on the optical path connecting between the first optical surface and the light emitting element in the first to third embodiments, it is also possible to dispose a light attenuation member at the first optical surface or the light-emitting surface of the light emitting element (light emission region) by coating the first optical surface or the light-emitting surface of the light emitting element (light emission region) with a material that selectively attenuates reception light through selective absorption of light of the wavelength of reception light and the like.

In addition, while the first optical surface is disposed at a position where the central axis thereof is aligned with the optical axis of the transmission light emitted from the light emitting element in the first to third embodiments, it may be disposed at a position deviated from the optical axis of the transmission light emitted from the light emitting element. At this time, an optical member such as a mirror or a filter that reflects or refracts light having the wavelength of the transmission light may be disposed between the light emitting element and the first optical surface such that the transmission light emitted from the light emitting element is delivered toward the first optical surface. Further, at this time, it is also possible to suppress the occurrence of cross talk due the reception light reaching the light emitting element by using, as the above-mentioned optical member, a member that does not reflect or refract the reception light entered from the second optical surface such that the light is not delivered to the first optical surface.

In addition, in the third embodiment, the two optical modules disposed at both end portions of optical transmission member 400 may each be optical module 100 of the first embodiment, or may each be optical module 500 of the second embodiment as long as the attenuation rate of transmission light at the optical path separation part (the attenuation rate of transmission light L1 at optical path separation part 360 in optical module 100 of the first embodiment; the attenuation rate of transmission light L3 at optical path separation part 660 in optical module 500 of the second embodiment), and the quantity of light from the optical path separation part to the light receiving element (the quantity of transmission light L2a from optical path separation part 360 to light receiving element 230 in optical module 100 of the first embodiment; the quantity transmission light L4b from optical path separation part 660 to light receiving element 220 in optical module 500 of the second embodiment) are appropriately adjusted.

In addition, a light attenuator, an antireflection film and the like may be disposed in the surface of the optical receptacle where transmission light refracted by the fifth optical surface reaches in the first and third embodiments. In this manner, it is possible to suppress reduction in sensitivity of light transmission and light reception due to the transmission light refracted at the fifth optical surface that is reflected to pass through the optical path of transmission light L1 or reception light L2. Likewise, in the second and third embodiments, a light attenuator, an antireflection film and the like may be disposed in the surface of the optical receptacle where transmission light transmitted through the connection surface reaches.

This application is entitled to and claims the benefit of Japanese Patent Application No. 2017-213719 filed on Nov. 6, 2017, the disclosure each of which including the specification, drawings and abstract is incorporated herein by reference in its entirety.

### INDUSTRIAL APPLICABILITY

The optical receptacle, the optical module and the optical transmission member according to the present invention are suitable for optical communications using an optical transmission member, for example.

### REFERENCE SIGNS LIST

100 Optical module
200 Photoelectric conversion device
210 Substrate
220 Light emitting element
230 Light receiving element
300 Optical receptacle
302 Positioning part
305 Leg part
310 First recess
320 Second recess
330 Third recess
340 Transmission light reflection part
350 Transmission surface
360 Optical path separation part
365 Separation unit
365a Fourth optical surface
365b Fifth optical surface
365c Connection surface
370 First optical surface
375 Light attenuation member
380 Second optical surface
390 Third optical surface
400 Optical transmission member
500 Optical module
600 Optical receptacle
620 Fourth recess
630 Fifth recess
640 Reception light reflection part
650 Transmission surface
660 Optical path separation part
665 Separation unit
665a Fourth optical surface
665b Fifth optical surface
665c Connection surface
700 Optical transmitter

1-9. (canceled)

10. An optical module comprising:
a photoelectric conversion device including a light emitting element and a light receiving element;
an optical receptacle configured to optically couple the light emitting element and an end surface of an optical transmission member, and optically couple the end surface of the optical transmission member and the light receiving element, the optical receptacle including:
a first optical surface configured to allow, to enter the optical receptacle, transmission light emitted from the light emitting element;
a second optical surface configured to emit, to outside of the optical receptacle, the transmission light entered from the first optical surface such that the transmission light entered from the first optical surface reaches the end surface of the optical transmission member, the second optical surface being configured to allow, to enter the optical receptacle, reception light emitted from the end surface of the optical transmission member;
a third optical surface configured to emit, to the outside of the optical receptacle, the reception light entered from the second optical surface such that the reception light entered from the second optical surface reaches the light receiving element; and
an optical path separation part configured to deliver, to the second optical surface, a part of the transmission light entered from the first optical surface, the optical path separation part being configured to deliver, to the third optical surface, a part of the reception light entered from the second optical surface,
wherein the optical path separation part is an optical surface including a fourth optical surface, and a fifth optical surface inclined with respect to the fourth optical surface,
wherein the fourth optical surface is disposed at an angle such that the part of the transmission light that has entered the optical receptacle and has reached the optical path separation part advances toward the second optical surface, and
wherein the fifth optical surface is disposed at an angle such that the part of reception light that has entered the optical receptacle and has reached the optical path separation part advances toward the third optical surface; and
a light attenuation member disposed on an optical path connecting between the first optical surface and the light emitting element, the light attenuation member being configured to attenuate the reception light that reaches the light emitting element from the optical path separation part.

11. The optical module according to claim 10, wherein the light emitting element and the light receiving element are disposed on a same plane.

12. An optical transmitter comprising:
an optical transmission member; and
two optical modules disposed at both end portions of the optical transmission member, each of the two optical modules being the optical module according to claim 10.

13. The optical module according to claim 10, wherein the optical path separation part has a shape in which a plurality of separation units are disposed, each of the plurality of separation units including the fourth optical surface and the fifth optical surface.

14. The optical module according to claim 10,
wherein the fourth optical surface allows, to pass through the fourth optical surface toward the second optical surface, the transmission light entered from the first optical surface; and
the fifth optical surface reflects, toward the third optical surface, the reception light entered from the second optical surface.

15. The optical module according to claim 14, further comprising a transmission light reflection part disposed on an optical path of the transmission light connecting between the first optical surface and the optical path separation part, the transmission light reflection part being configured to reflect, toward the optical path separation part, the transmission light that has entered the optical receptacle from the first optical surface.

16. The optical module according to claim 10,
wherein the fourth optical surface reflects, toward the second optical surface, the transmission light entered from the first optical surface; and
wherein the fifth optical surface allows, to pass through the fifth optical surface toward the third optical surface, the reception light entered from the second optical surface.

17. The optical module according to claim 16, further comprising a reception light reflection part disposed on an optical path of the transmission light connecting between the optical path separation part and the third optical surface, the reception light reflection part being configured to reflect, toward the third optical surface, reception light that has passed through the optical path separation part.

18. The optical module according to claim 10,
wherein a wavelength of the transmission light and a wavelength of the reception light are different from each other; and
wherein a transmittance of the light attenuation member for the wavelength of the reception light is smaller than a transmittance of the light attenuation member for the wavelength of the transmission light.

19. An optical receptacle as used in the optical module according to claim 10.

20. An optical receptacle as used in the optical module according to claim 11.
